(19) United States
(12) Patent Application Publication
(10) Pub. No.: US 2026/0182100 A1
(43) Pub. Date: Jun. 25, 2026

(54) SEMICONDUCTOR LIGHT-EMITTING DEVICE AND SEMICONDUCTOR LIGHT-EMITTING MODULE

(71) Applicant: STANLEY ELECTRIC CO., LTD., Tokyo (JP)

(72) Inventor: Maiko TANABE, Tokyo (JP)

(73) Assignee: STANLEY ELECTRIC CO., LTD., Tokyo (JP)

(21) Appl. No.: 19/412,925

(22) Filed: Dec. 9, 2025

(30) Foreign Application Priority Data
Dec. 20, 2024 (JP) 2024-225745

(51) Int. Cl. H10H 20/84; H10H 20/851; H10H 20/854; H10H 20/855; H10H 29/24; H10H 29/80; H10H 29/85; H10H 29/851; H10H 29/854

(52) U.S. Cl. CPC H10H 20/84; H10H 20/8514; H10H 20/854; H10H 20/855; H10H 29/24; H10H 29/842; H10H 29/8506; H10H 29/8512; H10H 29/854; H10H 20/8512

(57) ABSTRACT

A semiconductor light-emitting device includes: a semiconductor light-emitting element, a wavelength conversion member adhesively bonded onto a top surface of the semiconductor light-emitting element by a light-transmissive adhesion layer, and a light-transmissive coating layer that is disposed on a top surface of the wavelength conversion member and has a refractive index intermediate between that of the wavelength conversion member and that of an air layer. The light-transmissive coating layer is a glass coat layer or sintered nanoparticle body coat layer having a surface roughness within a range of 0.1 to 0.4 μm.

### BACKGROUND OF THE INVENTION

### Field of the Invention

The present disclosure relates to a semiconductor light-emitting device and a semiconductor light-emitting module, and more particularly to a semiconductor light-emitting device including a wavelength conversion element and a semiconductor light-emitting module including the semiconductor light-emitting device.

### Description of Related Art

Semiconductor light-emitting devices have been known that convert, using a wavelength conversion member, the wavelength of light emitted from a semiconductor light-emitting element to emit white light or light having color rendering properties. Such semiconductor light-emitting devices are used as light sources of lighting fixtures such as general lighting and exterior/interior lighting and as lamp devices such as vehicle lamps.

For example, Patent Literature 1 discloses a semiconductor light-emitting device that includes a thin film with a rough surface that is located on the outermost surface of a wavelength conversion layer from which wavelength-converted light is emitted, that has a property of repelling an uncured light-reflective member covering the side surfaces of the wavelength conversion layer, and that has a surface formed to follow the rough surface of the wavelength conversion layer. With such a semiconductor light-emitting device, the light emission efficiency is described as being improved, this improvement being due to suppression of the creeping up of the covering member onto the surface of the light-emitting layer.

Patent Literature 2 discloses a semiconductor light-emitting device including a moisture-resistant thin film disposed on a surface of a wavelength conversion layer. Such a semiconductor light-emitting device is described to reduce the occurrence of cracks in the covering member and, by extension, reduce light leakage.

### CITATION LIST

Patent Literature 1: Japanese Patent No. 6800702
Patent Literature 2: Japanese Patent No. 6800703

Further improvements in luminous flux and luminance are desired of semiconductor light-emitting devices that include a wavelength conversion member on their semiconductor light-emitting elements. With conventional semiconductor light-emitting devices, there have also been problems such as the existence of angular dependence in the chromaticity of light emitted from the wavelength conversion member. When the side surfaces of the wavelength conversion member are covered with a covering member such as a white resin, there have also been problems such as the covering member creeping up onto the surface of the wavelength conversion member, resulting in a decrease in the light emission efficiency.

### BRIEF SUMMARY OF THE INVENTION

The present disclosure has been achieved in view of the foregoing, and an object thereof is to provide a semiconductor light-emitting device and a semiconductor light-emitting module with improved luminous flux and luminance and a reduction in the angular dependence in the chromaticity. Another object of the present disclosure is to provide a semiconductor light-emitting device whose side surfaces are covered by a covering member without the covering member creeping up onto the surface of the wavelength conversion member, and to provide a semiconductor light-emitting module including the semiconductor light-emitting device.

According to an aspect of the present disclosure, a semiconductor light-emitting device includes:
a semiconductor light-emitting element;
a wavelength conversion member adhesively bonded onto a top surface of the semiconductor light-emitting element by a light-transmissive adhesion layer; and
a light-transmissive coating layer that is disposed on a top surface of the wavelength conversion member and has a refractive index intermediate between that of the wavelength conversion member and that of an air layer, wherein
the light-transmissive coating layer is a glass coat layer or sintered nanoparticle body coat layer having a surface roughness within a range of 0.1 to 0.4 μm.

According to another aspect of the present disclosure, a semiconductor light-emitting module includes:
the foregoing semiconductor light-emitting device;
a circuit substrate on which the semiconductor light-emitting device is mounted; and
a covering resin that surrounds and covers an entire side surface of the semiconductor light-emitting device while leaving an entire top surface of the semiconductor light-emitting device exposed.

### BRIEF DESCRIPTION OF THE DRAWINGS

These and other characteristics, features, and advantages of the present disclosure will become clear from the following description with reference to the accompanying drawings, wherein:

FIG. 1 is a sectional view schematically showing a semiconductor light-emitting device according to a first embodiment;

FIG. 2 is a diagram schematically showing a cross section of an interface portion between a phosphor plate and a light-transmissive coating layer;

FIG. 3 is a graph showing the increase rate of luminous flux in a case where the light-transmissive coating layer is provided on the phosphor plate, with a case where the light-transmissive coating layer is not provided as a reference (REF);

FIG. 4 is a graph showing the angular dependence in the chromaticity of emitted light in the case where the light-transmissive coating layer is provided, in comparison with the angular dependence in the chromaticity in the case without the light-transmissive coating layer;

FIG. 5 is a graph showing differences Δccx in the average values of ccx coordinates at angles of ±70° in samples EX1 to EX3 and CX1 to CX3;

FIG. 6 is a graph showing the luminance of emitted light in the case where the light-transmissive coating layer is provided, in comparison with the luminance of light emitted from a semiconductor light-emitting device without the light-transmissive coating layer;

FIG. 7 is a sectional view schematically showing a semiconductor light-emitting device according to a second embodiment;

FIG. 8 is a sectional view schematically showing a semiconductor light-emitting module according to a third embodiment;

FIG. 9 is a sectional view schematically showing a semiconductor light-emitting module according to a fourth embodiment;

FIG. 10A is a sectional view schematically showing a semiconductor light-emitting module according to a fifth embodiment; and

FIG. 10B is a plan view of the semiconductor light-emitting device according to the fifth embodiment, seen from the top surface side.

### DETAILED DESCRIPTION OF THE INVENTION

Preferred embodiments of the present disclosure will now be described. However, these embodiments may be modified and/or combined as appropriate. In the following description and accompanying drawings, substantially identical or equivalent parts are denoted by the same reference numerals for description.

### First Embodiment

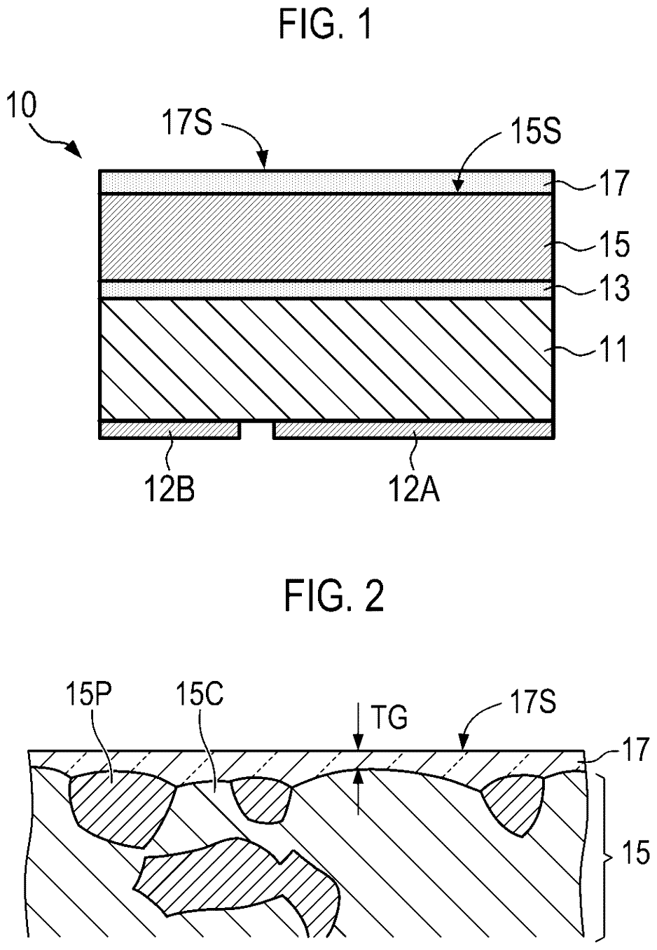

FIG. 1 is a sectional view schematically showing a semiconductor light-emitting device 10 according to a first embodiment of the present disclosure. The semiconductor light-emitting device 10 according to the present embodiment includes a semiconductor light-emitting element 11, a phosphor plate 15 that is a wavelength conversion member adhesively bonded to the top surface of the semiconductor light-emitting element 11 by an adhesion layer 13 which is a light-transmissive layer, and a light-transmissive coating layer 17 disposed on a top surface 15S of the phosphor plate 15.

The semiconductor light-emitting element 11 is a light-emitting diode (LED) that emits blue light. Specifically, the semiconductor light-emitting element 11 is a flip-chip LED having a rectangular parallelepiped shape. A p-electrode 12A and an n-electrode 12B that are driving electrodes of the semiconductor light-emitting element 11 are disposed on the back surface of the semiconductor light-emitting element 11. Instead of the flip-chip structure, an LED that has a metallic bonding structure may be used.

The phosphor plate 15 is a sintered-sheet phosphor plate obtained by dispersing a phosphor (such as YAG) in an alumina matrix. The phosphor plate 15 has a rectangular parallelepiped shape with a size substantially equivalent to that of the semiconductor light-emitting element 11. The phosphor plate 15 converts the blue light from the semiconductor light-emitting element 11 into yellow light, whereby white light is emitted from the top surface 15S of the phosphor plate 15.

More specifically, the phosphor plate 15 had ceramic (alumina: Al₂O₃) as a base material, with a phosphor composition of YAG:Ce and a phosphor particle diameter of 3 to 5 μm. The phosphor concentration (=phosphor/(phosphor+alumina)) was 20% to 30% by weight ratio.

The phosphor plate 15 is adhesively bonded, without gaps, to the semiconductor light-emitting element 11 by the adhesion layer 13, which is made of a material that is transparent when subjected to the light emitted from the semiconductor light-emitting element 11. For example, adhesives made of a silicone resin and the like may be used as the adhesion layer 13. However, this example is not restrictive.

The light-transmissive coating layer 17 on the phosphor plate 15 is a glass coat having a rectangular film shape, and is formed over the entire top surface of the phosphor plate 15, i.e., up to the outer edges of the phosphor plate 15. The light-transmissive coating layer 17 is formed by applying a solvent containing quartz (liquid) as a coating agent onto the top surface 15S (light emitting surface) of the phosphor plate 15, followed by firing. The coating agent is applied by spin coating. The sintering temperature is 500° C. and the sintering time is 1 to 10 hours, for example. Alcohol and other volatile solvents can be used as the solvent.

The light-transmissive coating layer 17 is not limited to quartz. For example, borosilicate glass can also be suitably used.

FIG. 2 is a diagram schematically showing a cross section of the interface portion between the phosphor plate 15 and the light-transmissive coating layer 17. The phosphor plate 15 contains phosphor particles 15P in ceramic 15C that is the base material. The light-transmissive coating layer 17 having an average thickness of TG is disposed on the phosphor plate 15. As employed herein, the average thickness TG refers to the average thickness of the light-transmissive coating layer across the area where the light-transmissive coating layer 17 is formed. In the present embodiment, the average thickness TG refers to the average thickness of the light-transmissive coating layer 17 across the area where the light-transmissive coating layer 17 is formed up to the outer edges of the phosphor plate 15.

The phosphor plate 15 had a rough surface, and the surface roughness Ra or arithmetic average roughness was greater than 0.4 μm. Specifically, the surface roughness Ra of the phosphor plate 15 was 0.4 to 0.5 μm. The surface roughness Ra of the light-transmissive coating layer 17 layer was 0.1 to 0.4 μm. In other words, the arithmetic average roughness (Ra) of the surface was reduced by the provision of the light-transmissive coating layer 17. The light-transmissive coating layer 17 had an average thickness TG of 0.2 to 0.8 μm.

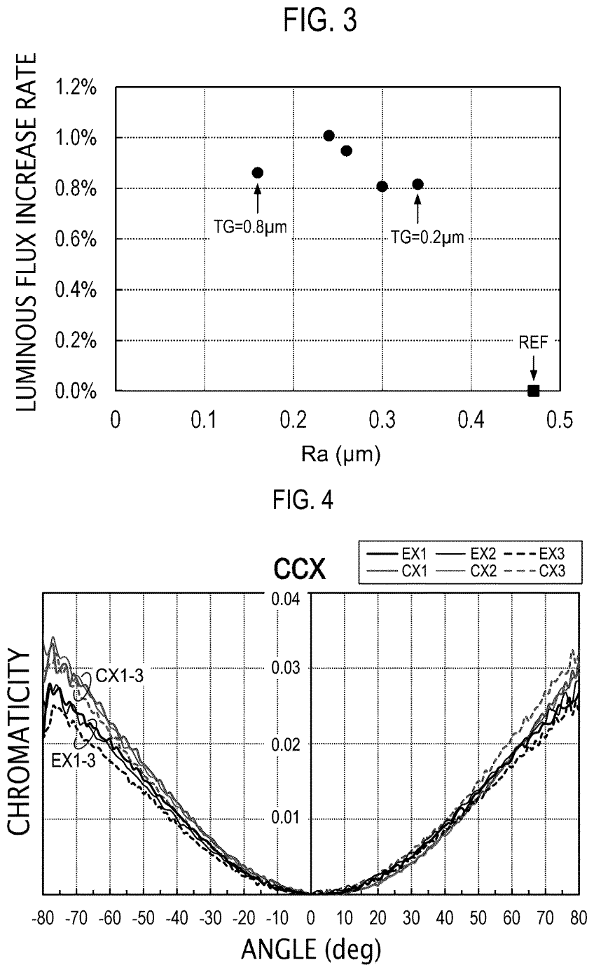

FIG. 3 is a graph showing the increase rate of luminous flux in cases where the light-transmissive coating layer 17 is provided on the phosphor plate 15, with a case where the light-transmissive coating layer 17 is not provided as a reference (REF). Specifically, FIG. 3 shows luminous flux increase rates in five cases where the light-transmissive coating layer 17 has an average thickness TG of 0.2 μm to 0.8 μm.

The light-transmissive coating layer 17 has a refractive index intermediate between that of the phosphor plate 15 and that of an air layer. Specifically, the ceramic (alumina) in the phosphor plate 15 has a refractive index of 1.77, and the YAG phosphor has a refractive index of 1.82.

If the light-transmissive coating layer 17 is not disposed on the phosphor plate 15 (in the graph, REF), the light extraction efficiency would decrease because of a large difference in refractive index compared to air. The surface roughness Ra of the phosphor plate 15 here was 0.47 μm.

If the top surface 15S of the phosphor plate 15 and the surface 17S of the light-transmissive coating layer 17 are flat, the luminous flux decreases compared to without the light-transmissive coating layer 17. Specifically, a simulation with the refractive index of the phosphor plate 15 set to 1.77 and the refractive index of the light-transmissive coating layer 17 set to 1.5 shows that the luminous flux decreases by 13% compared to a case without the light-transmissive coating layer 17 (REF).

Meanwhile, the surface 17S (light emitting surface) that is the top surface of the light-transmissive coating layer 17 has a predetermined surface roughness Ra. In other words, since the surface 17S of the light-transmissive coating layer 17 has a surface roughness Ra (rough surface) smaller than the wavelength of the emitted light, the refractive index between the light-transmissive coating layer 17 and air can be continuously changed. This can improve the light extraction efficiency and increase the luminous flux.

As shown in FIG. 3, it has been found that a luminous flux increase of 0.8% to 11% is obtained when the average thickness TG of the light-transmissive coating layer 17 is 0.2 μm to 0.8 μm. As the average thickness TG of the light-transmissive coating layer 17 increased from 0.2 μm to 0.8 μm, the surface roughness Ra of the light-transmissive coating layer 17 decreased from Ra=0.34 (μm) to Ra=0.16 (μm).

In other words, the surface roughness Ra of the light-transmissive coating layer 17 is preferably within the range of 0.1 to 0.4 μm, more preferably within the range of 0.16 to 0.34 μm.

The light-transmissive coating layer 17 preferably has an average thickness TG within the range of 0.2 to 0.8 μm. The reason is that an average thickness TG exceeding 0.8 μm can cause cracks in the glass after firing, and an average thickness TG below 0.2 μm can produce portions where the light-transmissive coating layer 17 is not formed on the phosphor plate 15 during spin coating.

According to the semiconductor light-emitting device 10, the high luminous flux of the emitted light leads to low power consumption. When a plurality of semiconductor light-emitting devices 10 are mounted on a substrate or the like, the number of devices can be reduced to achieve device miniaturization and cost reduction.

FIG. 4 shows the angular dependence in the chromaticity of the light emitted from the semiconductor light-emitting device 10 with the light-transmissive coating layer 17, in comparison with the angular dependence in the chromaticity of light emitted from a semiconductor light-emitting device without the light-transmissive coating layer 17. The vertical axis indicates the x (ccx) coordinate on the CIE chromaticity chart. FIG. 4 shows three samples EX1 to EX3 and three samples CX1 to CX3 of the respective semiconductor light-emitting devices. Samples EX1 to EX3 are ones where the light-transmissive coating layer 17 is provided on the phosphor plate 15. Samples CX1 to CX3 are ones where the light-transmissive coating layer 17 is not provided and the phosphor plate 15 is exposed at the top surface of the light-emitting device.

FIG. 5 shows differences Δccx in the average values of the ccx coordinates at angles of +70° in samples EX1 to EX3 and CX1 to CX3.

In the case where the light-transmissive coating layer 17 is provided (EX1 to EX3), it can be seen that the angular dependence in the chromaticity and Δccx are improved and that the color separation is reduced compared to the case without the light-transmissive coating layer 17. Scattering occurs at the interface between the phosphor plate 15 and the light-transmissive coating layer 17 and the interface between the light-transmissive coating layer 17 and the air layer, whereby the angular dependence in the chromaticity is improved. The smaller color separation can reduce a phenomenon where the peripheral area becomes yellowish and uneven in color (yellowing) when the semiconductor light-emitting device 10 is assembled into a lamp device, for example.

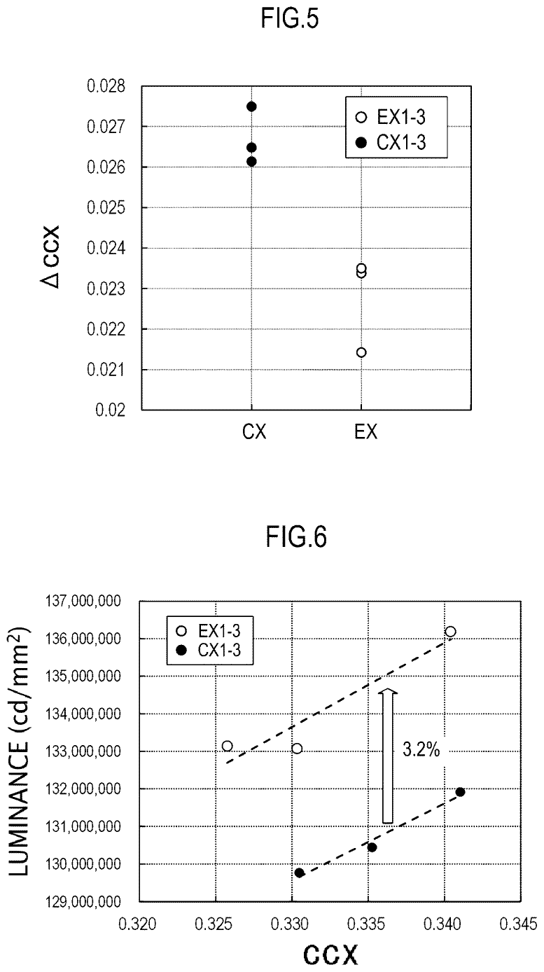

FIG. 6 shows the luminance (cd/mm²) of the light emitted from the semiconductor light-emitting device 10 in the case where the light-transmissive coating layer 17 is provided, in comparison with the luminance of the light emitted from the semiconductor light-emitting device without the light-transmissive coating layer 17.

In the case where the light-transmissive coating layer 17 is provided (EX1 to EX3), it can be seen that the luminance improves by approximately 3.2% compared to the case without the light-transmissive coating layer 17. The increase in luminance is greater than the increase in luminous flux (see FIG. 3).

In other words, the provision of the light-transmissive coating layer 17 reduces the angular dependence in the chromaticity, and the light directly above becomes more yellowish with an increase in luminance.

According to the semiconductor light-emitting device 10, the high luminous flux of the emitted light leads to low power consumption. When a plurality of semiconductor light-emitting devices 10 are mounted on a substrate or the like, the number of devices can be reduced for miniaturization and cost reduction.

As described above, according to the present disclosure, a semiconductor light-emitting device with improved luminous flux and luminance and a reduction in the angular dependence in the chromaticity can be provided.

### Second Embodiment

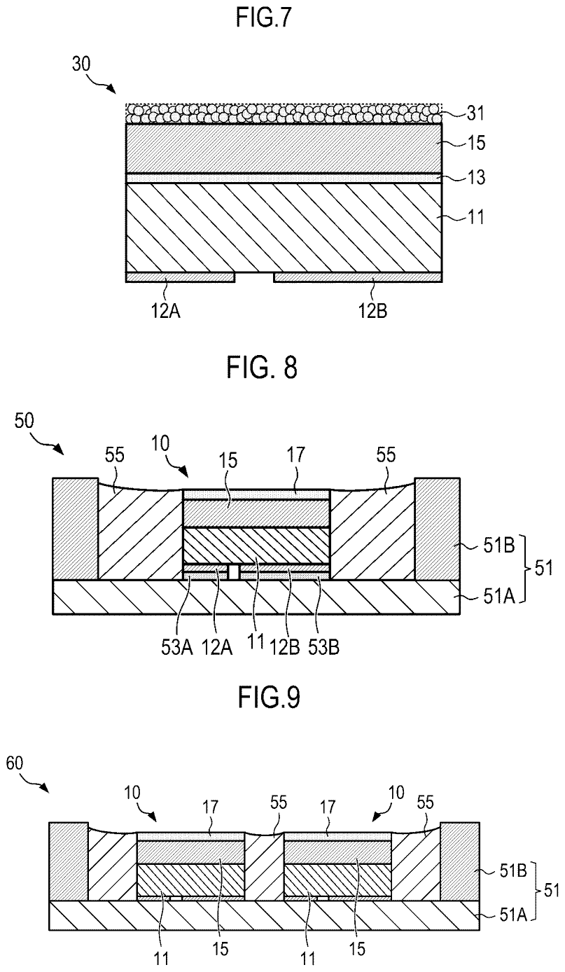

FIG. 7 is a sectional view schematically showing a semiconductor light-emitting device 30 according to a second embodiment of the present disclosure. The semiconductor light-emitting device 30 according to the present embodiment differs from the semiconductor light-emitting device 10 according to the first embodiment in that a light-transmissive coating layer 31, which is a sintered nanoparticle body, is disposed on the top surface 15S of the phosphor plate 15. The light-transmissive coating layer 31 has a refractive index intermediate between that of the phosphor plate 15 and that of the air layer.

More specifically, the light-transmissive coating layer 31 of the semiconductor light-emitting device 30 is a sintered nanoparticle body formed by sintering nano-size quartz particles (nanoparticles). Specifically, a solvent containing quartz particles with a particle diameter of 1 to 100 nm was applied onto the top surface 15S of the phosphor plate 15 by spin coating, followed by sintering, to form the light-transmissive coating layer 31. The sintering temperature was 1,000° C. to 3,000° C., and the sintering time was approximately 3 hours. The light-transmissive coating layer 31 is formed over the entire top surface of the phosphor plate 15.

An ideal antireflection film can be configured using the light-transmissive coating layer 31, a sintered nanoparticle body. The nanoparticles, which have a particle diameter that is not optically perceptible to the excitation light or the wavelength-converted light, exhibit an antireflection function. In other words, by forming the light-transmissive coating layer 31 with the sintered body of nanoparticles having a particle diameter smaller than the wavelengths of the excitation light and the wavelength-converted light, a function of continuously varying the refractive index between air and the phosphor plate 15 is produced, whereby the light extraction efficiency is improved. The light-transmissive coating layer 31 that is composed of a sintered nanoparticle body need only be configured so that the particle diameter of the nanoparticles and the diameters of gaps formed in the light-transmissive coating layer 31 by sintering the nanoparticles are smaller than the wavelength of the excitation light.

The coating material having the lowest refractive index is MgF₂, which has a refractive index of 1.38. In other words, sintered nanoparticle bodies can be used to form a coating layer having a refractive index substantially lower than that of MgF₂. The sintered nanoparticle body coating layer can thus form a coating layer having a refractive index intermediate between that of the nanoparticles and that of air, whereby a non-reflective or extremely low-reflective light-transmissive coating layer 31 can be implemented.

The nanoparticles are filled, without gaps, into the asperities (see FIG. 2) formed by the phosphor particles 15P and the ceramic 15C on the top surface 15S of the phosphor plate 15, and are subsequently sintered. Accordingly, generation of bubbles (voids) at the interface between the phosphor plate 15 and the light-transmissive coating layer 31 can be prevented.

The light-transmissive coating layer 31 may be either porous or nonporous.

The use of the light-transmissive coating layer 31 that is a sintered nanoparticle body coating layer can provide a semiconductor light-emitting device with high light extraction efficiency and with improved luminous flux and luminance.

### Third Embodiment

FIG. 8 is a sectional view schematically showing a semiconductor light-emitting module 50 according to a third embodiment of the present disclosure. The semiconductor light-emitting module 50 includes a module substrate 51, the semiconductor light-emitting device 10 according to the first embodiment, which is accommodated in the module substrate 51, and a covering resin 55 that covers the side surfaces of the semiconductor light-emitting device 10.

More specifically, the module substrate 51 includes a circuit substrate 51A and a frame 51B erected on the circuit substrate 51A. The semiconductor light-emitting device 10 is mounted on the circuit substrate 51A.

Specifically, a p-mounting electrode 53A and an n-mounting electrode 53B are disposed on the circuit substrate 51A. The p-electrode 12A and the n-electrode 12B of the semiconductor light-emitting element 11 are bonded and electrically connected to the p-mounting electrode 53A and the n-mounting electrode 53B, respectively.

The four side surfaces of the semiconductor light-emitting device 10 are covered by the covering resin 55. More specifically, the space between the module substrate 51 and the semiconductor light-emitting device 10 is filled with the covering resin 55. The covering resin 55 surrounds and covers the side surfaces of the semiconductor light-emitting device 10. The top surface of the semiconductor light-emitting device 10, i.e., the top surface of the light-transmissive coating layer 17 is entirely exposed and not covered by the covering resin 55.

The covering resin 55 may be a light-reflective resin containing particles such as TiO₂ (so-called white resin). The covering resin 55 is not limited to a light-reflective white resin, and may be a light-absorptive resin (so-called black resin).

Conventionally, the phosphor plate 15 has a rough surface, and there has been a problem that the covering resin creeps up onto the surface due to capillary action, making it difficult to form the resin portions that cover only the side surfaces of the semiconductor light-emitting device 10. Since the light-transmissive coating layer 17 of the semiconductor light-emitting device 10 according to the present embodiment has a surface roughness Ra lower than that of the phosphor plate 15, the covering resin 55 can be formed without creeping up onto the light-transmissive coating layer 17. Specifically, the inner edges of the surface of the covering resin 55 match the outer edges of the light-transmissive coating layer 17. This configuration can prevent a drop in the light extraction efficiency due to the creeping up of the covering resin 55 onto the top surface of the light-transmissive coating layer 17.

Since the surface roughness Ra of the light-transmissive coating layer 17 is low, dust is less likely to adhere. Moreover, since the surface of the phosphor plate 15 is covered by the light-transmissive coating layer 17, the moisture resistance improves.

While the semiconductor light-emitting device 10 according to the first embodiment is described to be mounted in the module substrate 51, the semiconductor light-emitting device 30 according to the second embodiment may be mounted instead.

While the module substrate 51 is described to be composed of the circuit substrate 51A and the frame 51B, the circuit substrate 51A and the frame 51B may be integrally formed to constitute the module substrate 51. Alternatively, the frame 51B may be omitted. For example, the module substrate 51 may be a lead frame.

As described above, according to the semiconductor light-emitting module 50, a semiconductor light-emitting module can be provided that includes the semiconductor light-emitting device of the foregoing embodiment with improved luminous flux and luminance and a reduction in the angular dependence in the chromaticity and where the creeping up of the covering resin onto the top surface (light-emitting surface) of the semiconductor light-emitting device is prevented.

### Fourth Embodiment

FIG. 9 is a sectional view schematically showing a semiconductor light-emitting module 60 according to a fourth embodiment of the present disclosure. The semiconductor light-emitting module 60 includes a module substrate 51, a plurality of semiconductor light-emitting devices 10 according to the first embodiment, and a covering resin 55 that covers the side surfaces of the plurality of semiconductor light-emitting devices 10.

The plurality of semiconductor light-emitting devices 10 are electrically connected to and mounted on p-mounting elements and n-mounting elements (not shown) disposed on the circuit substrate 51A.

The space between the module substrate 51 and the plurality of semiconductor light-emitting devices 10 and the space between the adjoining ones of the semiconductor light-emitting devices 10 are filled with the covering resin 55. The side surfaces of the plurality of semiconductor light-emitting devices 10 are entirely covered by the covering resin 55.

As described above, the covering resin 55 is a light-reflective resin. The covering resin 55 is formed without creeping up onto the respective light-transmissive coating layers 17 of the plurality of semiconductor light-emitting devices 10. Semiconductor light-emitting devices 30 according to the second embodiment may be mounted instead of the semiconductor light-emitting devices 10.

The semiconductor light-emitting module 60 according to the fourth embodiment has the same advantages as those of the semiconductor light-emitting module 50 according to the third embodiment. According to the semiconductor light-emitting module 60, a semiconductor light-emitting module can be provided that includes the semiconductor light-emitting devices of the foregoing embodiment with improved luminous flux and luminance and a reduction in the angular dependence in the chromaticity and where the creeping up of the covering resin onto the top surfaces (light-emitting surfaces) of the semiconductor light-emitting devices is prevented.

The semiconductor light-emitting devices 10 and 30 have high luminous flux and high luminance, which lead to low power consumption. The number of semiconductor light-emitting devices to be mounted in the semiconductor light-emitting module 60 can therefore be reduced for miniaturization and construction reduction.

### Fifth Embodiment

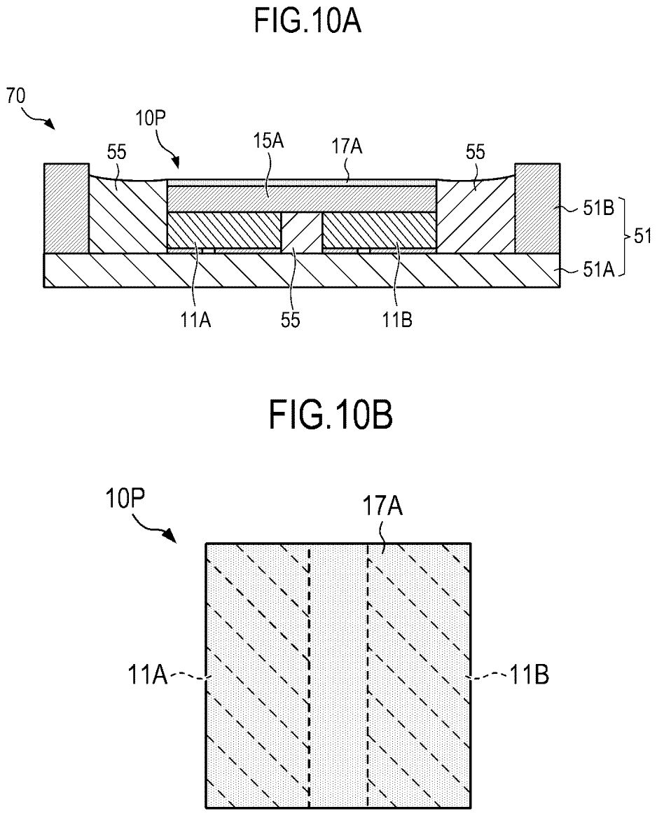

FIG. 10A is a sectional view schematically showing a semiconductor light-emitting module 70 according to a fifth embodiment of the present disclosure. The semiconductor light-emitting module 70 includes a module substrate 51, a semiconductor light-emitting device 10P including a plurality of light emitting elements, and a covering resin 55 that covers the side surfaces of the semiconductor light-emitting device 10P.

FIG. 10B is a schematic plan view of the semiconductor light-emitting device 10P seen from the top surface side. In the present embodiment, the semiconductor light-emitting device 10P includes two semiconductor light-emitting elements 11A and 11B having a rectangular parallelepiped shape of the same size.

The two semiconductor light-emitting elements 11A and 11B are separated from each other and have an aligned positional relationship. In a top view, the semiconductor light-emitting elements 11A and 11B have a rectangular shape. A phosphor plate 15A common to the semiconductor light-emitting elements 11A and 11B is adhesively bonded to the top surfaces of the semiconductor light-emitting elements 11A and 11B to match the entire perimeter of the semiconductor light-emitting elements 11A and 11B by an adhesion layer (not shown).

A light-transmissive coating layer 17A is disposed on the phosphor plate 15A. The light-transmissive coating layer 17A is a glass coat having a rectangular film shape, and is formed over the entire top surface of the phosphor plate 15A.

As shown in FIG. 10A, the semiconductor light-emitting elements 11A and 11B are electrically connected to and mounted on p-mounting elements and n-mounting elements (not shown) disposed on the circuit substrate 51A.

The space between the module substrate 51 and the semiconductor light-emitting device 10P and the space between the semiconductor light-emitting element 11A and the semiconductor light-emitting element 11B are filled with the covering resin 55, whereby the side surfaces of the semiconductor light-emitting device 10P are entirely covered by the covering resin 55.

The covering resin 55 is formed without creeping up onto the light-transmissive coating layer 17A of the semiconductor light-emitting device 10P. The light-transmissive coating layer 17A may be made of the same glass coat as the light-transmissive coating layer 17 according to the first embodiment. Alternatively, the coating layer of the same sintered nanoparticle body as the light-transmissive coating layer 31 according to the second embodiment may be used.

While the semiconductor light-emitting device 10P is described to include the two semiconductor light-emitting elements 11A and 11B of the same size, it is sufficient if a plurality of semiconductor light-emitting elements and a common phosphor plate whose size and shape match the perimeter of the entire top surface of the plurality of semiconductor light-emitting element are provided. In such a case, the plurality of semiconductor light-emitting elements do not necessarily need to have the same size.

The semiconductor light-emitting module 70 according to the fifth embodiment has the same advantages as those of the semiconductor light-emitting modules 50 and 60 according to the third and fourth embodiments. In addition, since the common phosphor plate is disposed on the plurality of semiconductor light-emitting elements, a semiconductor light-emitting module with even smaller angular dependence in the chromaticity, greater luminous flux, and higher luminance can be provided.

The present invention is not limited to the content of the foregoing embodiments, and can be modified and applied without departing from the scope of the present disclosure.

For example, while the semiconductor light-emitting devices according to the foregoing embodiments are described to have a rectangular parallelepiped shape, this is not restrictive. For example, the semiconductor light-emitting devices may have a cylindrical shape, an elliptical cylindrical shape, and the like.

### REFERENCES SIGNS LIST

10, 10P, 30: semiconductor light-emitting device
11, 11A, 11B: semiconductor light-emitting element
12A: p-electrode
12B: n-electrode
13: adhesion layer
15, 15A: phosphor plate
15C: ceramic
15P: phosphor particles
17, 17A, 31: light-transmissive coating layer
50, 60, 70: semiconductor light-emitting module
51: module substrate
51A: circuit substrate
51B: frame
53A, 53B: mounting electrode
55: covering resin

What is claimed is:

1. A semiconductor light-emitting device comprising:
a semiconductor light-emitting element;
a wavelength conversion member adhesively bonded onto a top surface of the semiconductor light-emitting element by a light-transmissive adhesion layer; and
a light-transmissive coating layer that is disposed on a top surface of the wavelength conversion member and has a refractive index intermediate between that of the wavelength conversion member and that of an air layer, wherein
the light-transmissive coating layer is a glass coat layer or sintered nanoparticle body coat layer having a surface roughness within a range of 0.1 to 0.4 μm.

2. The semiconductor light-emitting device according to claim 1, wherein the wavelength conversion member is a phosphor plate that is made of ceramic containing phosphor particles and has a surface roughness exceeding 0.4 μm.

3. The semiconductor light-emitting device according to claim 1, wherein the glass coat layer is made of quartz or borosilicate glass.

4. The semiconductor light-emitting device according to claim 1, wherein the glass coat layer has an average thickness within a range of 0.2 to 0.8 μm.

5. The semiconductor light-emitting device according to claim 1, wherein the sintered nanoparticle body coat layer has a refractive index lower than that of MgF₂.

6. The semiconductor light-emitting device according to claim 1, comprising a plurality of the semiconductor light-emitting elements; and
wherein the wavelength conversion member is adhesively bonded onto top surfaces of the semiconductor light-emitting elements to match an entire perimeter of the semiconductor light-emitting elements.

7. A semiconductor light-emitting module comprising:
the semiconductor light-emitting device according to claim 1;
a circuit substrate on which the semiconductor light-emitting device is mounted; and
a covering resin that surrounds and covers an entire side surface of the semiconductor light-emitting device while leaving an entire top surface of the semiconductor light-emitting device exposed.

8. The semiconductor light-emitting module according to claim 7, comprising a plurality of the semiconductor light-emitting devices mounted on the circuit substrate.

9. The semiconductor light-emitting module according to claim 7, wherein:
the circuit substrate includes a frame erected on the circuit substrate; and
a space between the semiconductor light-emitting device and the frame is filled with the covering resin.
